(19) United States
(12) Patent Application Publication
(10) Pub. No.: US 2012/0067394 A1
(43) Pub. Date: Mar. 22, 2012

(54) Solar Cell Apparatus

(76) Inventor: Suk Jae Jee, Seoul (KR)

(21) Appl. No.: 13/321,718

(22) PCT Filed: Jun. 30, 2010
(86) PCT No.: PCT/KR10/04257

§ 371 Date: Nov. 21, 2011

(30) Foreign Application Priority Data
Jun. 30, 2009 (KR) 10-2009-0058900

(51) Int. Cl. H01L 31/042

(52) U.S. Cl. 136/244

(57) ABSTRACT

Provided is a solar cell apparatus. The solar cell apparatus includes a substrate, a plurality of first cells disposed on the substrate, a plurality of second cells disposed on the substrate, and a first bus bar disposed between the first cells and the second cells, the first bus bar being connected to the first cells and the second cells.

### TECHNICAL FIELD

Embodiments relate to a solar cell apparatus.

### BACKGROUND ART

As the demand of energy increases in recent years, solar cells that convert solar energy into electrical energy are being developed.

In particular, each of the solar cells includes a plurality of layers such as a glass substrate, a metal backside electrode layer, a P-type CIGS-based light absorption layer, a high resistance buffer layer, and an N-type window layer.

Also, the solar cells have a structure in which the cells are connected to each other in parallel or in series.

### DISCLOSURE

### Technical Problem

Embodiments provide a solar cell apparatus which reduces current loss, has a simple structure, and includes cells connected to each other in parallel.

### Technical Solution

In one embodiment, a solar cell apparatus includes: a substrate; a plurality of first cells disposed on the substrate; a plurality of second cells disposed on the substrate; and a first bus bar disposed between the first cells and the second cells, the first bus bar being connected to the first cells and the second cells.

In another embodiment, a solar cell apparatus includes: a substrate; a first cell disposed on the substrate; a second cell disposed on the substrate, the second cell being spaced from the first cell; and a bus bar disposed between the first cell and the second cell, the bus bar being electrically connected to the first cell and the second cell.

In further another embodiment, a solar cell apparatus includes: a first bus bar extending in a first direction; a second bus bar extending alongside of the first bus bar; a third bus bar extending alongside of the first bus bar, the third bus bar being electrically connected to the second bus bar; a plurality of first cells disposed between the first bus bar and the second bus bar; and a plurality of second cells disposed between the first bus bar and the third bus bar.

### Advantageous Effects

In the solar cell apparatus according to the embodiments, the first bus bar is disposed at the central portion, and the cells are disposed on both sides of the first bus bar. Also, in the solar cell apparatus according to the embodiments, the second bus bar and the third bus bar are disposed on both ends of the substrate.

Thus, the cells disposed on both sides of the first bus bar are connected to each other in parallel. Here, the current generated by the solar energy moves from both ends to the first bus bar disposed at the central portion or from the first bus bar disposed at the central portion to the second bus bar and the third bus bar, which are disposed on both ends.

Thus, in the solar cell apparatus according to an embodiment, the electrons move a relatively short distance when compared to a solar cell in which electrons move from one end to the other end.

Thus, the solar cell apparatus according to an embodiment has improved efficiency.

Also, in the solar cell apparatus according to an embodiment, the electrons move in directions opposite to each other using the first bus bar disposed at the central portion.

Thus, in the solar cell apparatus according to an embodiment, the cells connected in series are also connected in parallel. Thus, in the solar cell apparatus according to an embodiment, the cells are disposed in a sample structure, and the cells are connected to each other in parallel.

### DESCRIPTION OF DRAWINGS

FIG. 1 is a plan view of a solar cell apparatus according to an embodiment.

FIG. 2 is a circuit view of a solar cell apparatus according to an embodiment.

FIG. 3 is a sectional view taken along line A-A′ of FIG. 1.

FIG. 4 is a plan view of a solar cell apparatus according to another embodiment.

FIG. 5 is a circuit view of a solar cell apparatus according to another embodiment.

FIG. 6 is a sectional view taken along line B-B′ of FIG. 4.

FIG. 7 is a plan view of a solar cell apparatus according to another embodiment.

FIG. 8 is a circuit view of a solar cell apparatus according to another embodiment.

FIG. 9 is a sectional view taken along line C-C′ of FIG. 7.

### MODE FOR INVENTION

In the description of embodiments, it will be understood that when a layer, film, electrode, groove, member, bar or layer is referred to as being ‘on’ another layer (or film), region, pad or pattern, the terminology of ‘on’ and ‘under’ includes both the meanings of ‘directly’ and ‘indirectly’. Further, the reference about ‘on’ and ‘under’ each layer will be made on the basis of drawings. In the drawings, the thickness or size of each layer is exaggerated for convenience in description and clarity. Also, the size of each element does not entirely reflect an actual size.

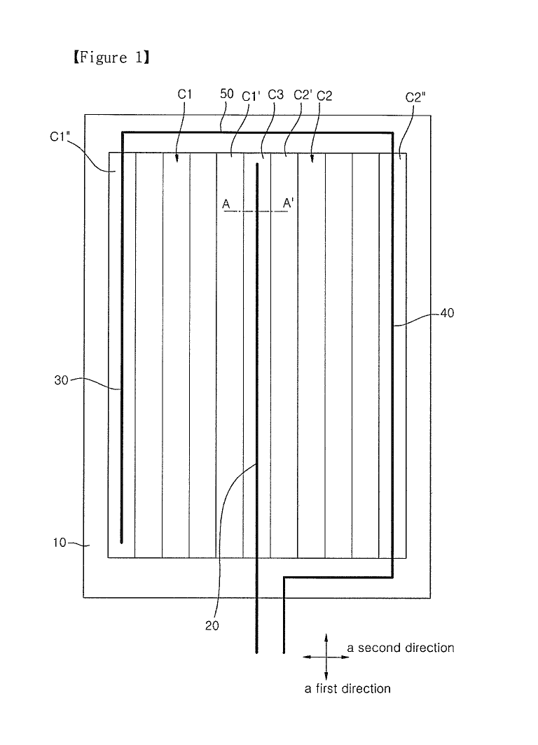

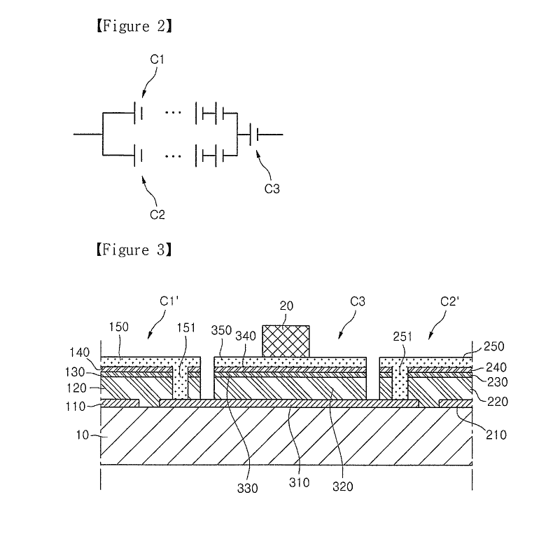

FIG. 1 is a plan view of a solar cell apparatus according to an embodiment. FIG. 2 is a circuit view of a solar cell apparatus according to an embodiment. FIG. 3 is a sectional view taken along line A-A′ of FIG. 1.

Referring to FIGS. 1 to 3, a solar cell apparatus according to an embodiment includes a support substrate 10, a plurality of first cells C1, a plurality of second cells C2, a third cell C3, a first bus bar 20, a second bus bar 30, a third bus bar 40, and a connection part 50.

The support substrate 10 has a plate shape. The support substrate 10 supports the first cells C1, the second cells C2, the third cell C3, the first to third bus bars 20, 30, and 40, and the connection part 50.

The support substrate 10 may be a glass substrate, a plastic substrate, or a metal substrate. In further detail, the support substrate 10 may be a soda-lime glass substrate.

The first cells C1 are disposed on the support substrate 10. The first cells C1 are connected to each other in series. The first cells C1 has a shape extending in a first direction. That is, the first cells C1 are disposed alongside with each other. The first cells C1 may be disposed parallel to each other.

The first cells C1 are disposed between the first bus bar 20 and the second bus bar 30 when viewed in a plan view.

Referring to FIG. 3, each of the first cells C1 includes a first backside electrode 110, a first light absorption part 120, a first buffer 130, a first high resistance buffer 140, and a first window 150.

The first backside electrode 110 is disposed on the support substrate 10. The first backside electrode 110 may be a conductor. Examples of materials used for the first backside electrode 110 may include molybdenum, etc.

The first light absorption part 120 is disposed on the first backside electrode 110. The first light absorption part 120 may include group I-III-VI compounds. For example, the first light absorption part 120 may have a copper indium gallium selenide (Cu(In,Ga)Se₂; CIGS) crystal structure, a copper indium selenide crystal structure, or a copper gallium selenide crystal structure.

The first light absorption part 120 may have an energy band gap of about 1 eV to about 1.8 eV.

The first buffer 130 is disposed on the first light absorption part 120. Examples of materials used for the first buffer 130 may include cadmium sulfide, etc.

The first high resistance buffer 140 is disposed on the first buffer 130. Examples of materials used for the first high resistance buffer 140 may include undoped zinc oxide, etc.

The first window 150 is disposed on the first high resistance buffer 140. Examples of materials used for the first window 150 may be undoped zinc oxide, etc.

The second cells C2 is disposed on the support substrate 10. The second cells C2 are disposed in a region adjacent to a region in which the first cells C1. When viewed in a plan view, the second cells C2 is disposed between the first bus bar 20 and the third bus bar 40.

The second cells C2 are connected to each other in series. The second cells C2 may have a shape extending in the first direction. That is, the second cells C2 extend in the first direction. The second cells C2 are disposed alongside with each other. The second cells C2 may be disposed parallel to each other.

That is, when viewed in a plan view, the first cells C1 and the second cells C2 are disposed on positions opposite to each other with the first bus bar 20 therebetween.

Referring to FIG. 3, each of the second cells C1 includes a second backside electrode 210, a second light absorption part 220, a second buffer 230, a second high resistance buffer 240, and a second window 250.

The second backside electrode 210 is disposed on the support substrate 10. The second backside electrode 210 may be a conductor. Examples of materials used for the second backside electrode 210 may include molybdenum, etc.

The second light absorption part 220 is disposed on the second backside electrode 210. The second light absorption part 220 may include group I-III-VI compounds. The second light absorption part 220 may have an energy band gap of about 1 eV to about 1.8 eV.

The second buffer 230 is disposed on the second light absorption part 220. Examples of materials used for the second buffer 230 may include cadmium sulfide, etc.

The second high resistance buffer 240 is disposed on the second buffer 230. Examples of materials used for the second high resistance buffer 240 may include undoped zinc oxide, etc.

The second window 250 is disposed on the second high resistance buffer 240. Examples of materials used for the second window 250 may be intrinsic zinc oxide(iZO), etc.

The third cell C3 is disposed on the support substrate 10. Also, the third cell C3 is disposed between the support substrate 10 and the first bus bar 20.

The third cell C3 is disposed between the first cells C1 and the second cells C2. Similarly, when viewed in a plan view, the first cells C1 and the second cells C2 are disposed on positions opposite to each other with the third cell C3 therebetween.

The third cell C3 is disposed in a region between a region in which the first cells C1 are disposed and a region in which the second cells C2 are disposed. The third cell C3 has a shape longitudinally extending in the first direction.

The third cell C3 is connected to the first cells C1 and the second cells C2. In detail, the third cell C3 is electrically connected to the first cells C1 and the second cells C2. In further detail, the third cell C3 is connected to a first cell C1′ most adjacent to the third cell C3 and a second cell C2′ most adjacent to the third cell C3.

Also, the third cell C3 is connected to the first bus bar 20. The third cell C3 may directly contact the first bus bar 20. The third cell C3 is electrically connected to the first bus bar 20.

Referring to FIG. 3, the third cell C3 includes a third backside electrode 310, a third light absorption part 320, a third buffer 330, a third high resistance buffer 340, and a third window 350.

The third backside electrode 310 is disposed on the support substrate 10. The third backside electrode 310 may be a conductor. Examples of materials used for the third backside electrode 310 may include molybdenum, etc.

The third light absorption part 320 is disposed on the third backside electrode 310. The third light absorption part 320 may include group I-III-VI compounds. The third light absorption part 320 may have an energy band gap of about 1 eV to about 1.8 eV.

The third buffer 330 is disposed on the third light absorption part 320. Examples of materials used for the third buffer 330 may include cadmium sulfide, etc.

The third high resistance buffer 340 is disposed on the third buffer 330. Examples of materials used for the third high resistance buffer 340 may include undoped zinc oxide, etc.

The third window 350 is disposed on the third high resistance buffer 340. Examples of materials used for the third window 350 may include zinc oxide doped with aluminum.

Also, the third backside electrode 310 is connected to the first window 150 of the first cell C1′ adjacent thereto. In further detail, the third backside electrode 310 is connected to a first connection electrode 151 extending from the first window 150 of the first cell C1′ adjacent thereto.

Also, the third backside electrode 310 is connected to the second window of the second cell C2′ adjacent thereto. In further detail, the third backside electrode 310 is connected to a second connection electrode 251 extending from the second window 250 of the second cell C2′ adjacent thereto.

As a result, the third cell C3 is connected to the first cells C1 in series, and simultaneously, connected to the second cells C2 in series.

The third cell C3 has a plane area greater than a mean area of the first cells C1 and a mean area of the second cells C2. In further detail, the third cell C3 has the plane area greater than or equal to the sum of the mean area of the first cells C1 and the mean area of the second cells C2.

An effective area (the plane area of the third cell C3 except an area in which the first bus bar is covered) of the third cell C3 is substantially equal to the sum of a plane area of each of the first cells C1 and a plane area of each of the second cells C2.

As a result, a current amount of the third cell C3 is equal to or greater than the sum of a current amount of each of the first cells C1 and a current amount of each of the second cells C2.

Thus, an output of the entire solar cell apparatus is not be deteriorated by the third cell C3.

The first bus bar 20 is disposed at a central portion of the support substrate 10. For example, the first bus bar 20 may be disposed at a center of the support substrate 10.

The first bus bar 20 is disposed on the third cell C3. The first bus bar 20 is disposed between the first cells C1 and the second cells C2. The first bus bar 20 is disposed in a region between the region in which the first cells C1 are disposed and the region in which the second cells C2 are disposed.

The first bus bar 20 is connected to the third cell C3. The first bus bar 20 is electrically connected to the third cell C3. The first bus bar 20 contacts the third cell C3. In further detail, the first bus bar 20 may directly contact the third cell C3.

Also, the first bus bar 20 is connected to the third window 350. The first bus bar 20 is electrically connected to the third window 350. The first bus bar 20 contacts the third window 350. In further detail, the first bus bar 20 may directly contact the third window 350.

The first bus bar 20 is electrically connected to the first cells C1 and the second cells C2 through the third cell C3.

The first bus bar 20 extends corresponding to the third cell C3. The first bus bar 20 extends in the first direction.

The second bus bar 30 is disposed on an edge of the support substrate 10. Also, the second bus bar 30 is disposed on one of the first cells Cl. In further detail, the second bus bar 30 is disposed on a first outermost cell C1′.

Also, the second bus bar 30 is connected to the first cells C1. In further detail, the second bus bar 30 is electrically connected to the first cells C1. In further detail, the second bus bar 30 directly contacts the first outermost cell C1′. That is, the second bus bar 30 directly contacts the first window of the first outermost cell C1′ and is electrically connected to the first cells C1.

The third bus bar 40 is connected to the second cells C2. In further detail, the third bus bar 40 is electrically connected to the second cells C2. In further detail, the third bus bar 40 directly contacts the second outermost cell C2″. That is, the third bus bar 40 directly contacts the second window of the second outermost cell C2″ and is electrically connected to the second cells C2.

The connection part 50 connects the second bus bar 30 to the third bus bar 40. The connection part 50 is disposed in an inactive region in which the first cells C1, the second cells C2, and the third cell C3 are not disposed.

The connection part 50 may be integrated with the second bus bar 30 and the third bus bar 40.

The first to third bus bars 20, 30, and 40 and the connection part 50 are realized as a conductor. For example, the first to third bus bars 20, 30, and 40 and the connection part 50 may be conductive tape. Examples of materials used for the first to third bus bars 20, 30, and 40 and the connection part 50 may include copper, silver, or aluminum.

Electrons generated in the first cells C1 move from the outside to the first bus bar 20. That is, the electrons generated from the first cells C1 move from the second bus bar 30 to the first bus bar 20 in the second direction substantially perpendicular to the first direction. That is, current generated from the first cells C1 flows from a central portion to the outside.

Similarly, electrons generated in the second cells C2 move from the outside to the first bus bar 20. That is, the electrons generated from the second cells C2 from the third bus bar 40 to the first bus bar 20 in the second direction substantially perpendicular to the first direction. That is, current generated from the second cells C2 flows from a central portion to the outside.

That is, in the solar cell apparatus according to an embodiment, the generated electrons move from the outside to the first bus bar 20 that is disposed at the central portion.

Thus, in the solar cell apparatus according to an embodiment, the electrons move a relatively short distance when compared to a solar cell in which electrons move from one end to the other end.

Thus, the solar cell apparatus according to an embodiment has improved efficiency.

Also, in the solar cell apparatus according to an embodiment, the electrons move in directions opposite to each other using the first bus bar 20 disposed at the central portion.

Thus, in the solar cell apparatus according to an embodiment, the cells connected in series are also connected in parallel. That is, in the solar cell apparatus according to an embodiment, the first cells C1 and the second cells C2 are disposed along one line in the second direction.

Thus, in the solar cell apparatus according to an embodiment, the cells are disposed in a sample structure, and the first cells C1 and the second cells C2 are connected to each other in parallel.

Also, although three bus bars are provided and the plurality of cells is respectively disposed between the bus bars in the present embodiment, the present disclosure is not limited thereto. For example, the plurality of cells may be respectively disposed between a greater number of bus bars.

For example, five bus bars are disposed alongside with each other, and a plurality of first cells, a plurality of second cells, a plurality of third cells, and a plurality of fourth cells may be respectively disposed between the five bus bars.

Here, the first cells may be connected to each other in series, and the second cells may be connected to each other in series. Similarly, the third cells may be connected to each other in series, and the fourth cells may be connected to each other in series.

Also, the first cells, the second cells, the third cells, and the fourth cells may be connected to each other in parallel. Here, a central bus bar of the five bus bars and bus bars of both outsides of the five bus bars may be electrically connected to each other, and the remaining bus bars may be electrically connected to each other.

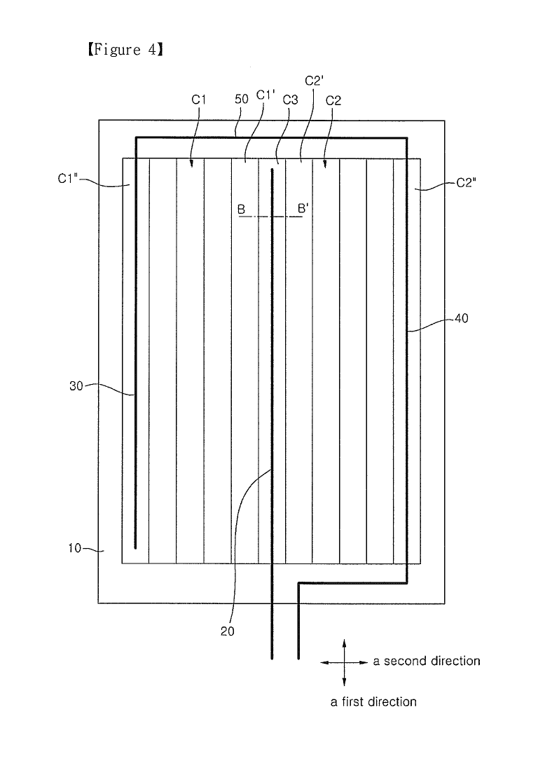

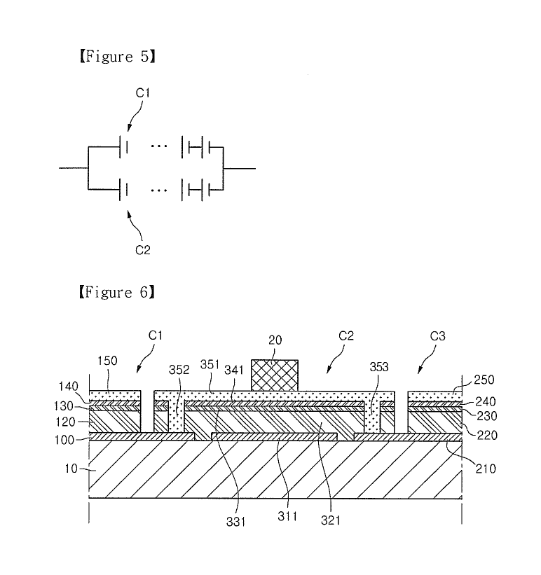

FIG. 4 is a plan view of a solar cell apparatus according to another embodiment. FIG. 5 is a circuit view of a solar cell apparatus according to another embodiment. FIG. 6 is a sectional view taken along line B-B′ of FIG. 4. The present embodiment refers to the previously described embodiment, and also, the third cell will be additionally described. In description of the present embodiment, this embodiment may be substantially the same as the foregoing embodiment, except changed parts of the present embodiment.

Referring to FIGS. 4 to 6, a third cell C3 does not substantially generate electricity. That is, the third cell C3 does not transfer electrons generated using solar energy to a first bus bar 20.

A third window 350 is connected to a first backside electrode 110 of a first cell C1′ adjacent thereto. Also, the third window 350 is connected to a second backside electrode 210 of a second cell C2′ adjacent thereto.

In further detail, a first connection electrode 352 extending from the third window 350 contacts the first backside electrode 110, and a second connection electrode 353 extending from the third window 350 contacts the second backside electrode 210.

Therefore, the first bus bar 20 is connected to first cells C1 through the third window 350 and the first connection electrode 352. Also, the first bus bar 20 is connected to second cells C2 through the third window 350 and the second connection electrode 353.

Since the third cell C3 does not substantially generate electricity, it is not necessary to provide a large area to the third cell C3. Thus, the third cell C3 may have a plane area substantially equal to that of the first bus bar 20.

Electrons generated in the first cells C1 and the second cells C2 move from a central portion to the outside. That is, current generated in the first cells C1 and the second cells C2 flows from the outside to the central portion.

Thus, when a second bus bar 30 contacts a first window 150 of a first outermost cell C1′, current generated in the first window 150 may flow through the second bus bar 30.

Substantially, the first bus bar 20 is connected to the first backside electrode 110 of the first cell C1′ adjacent thereto, and the second bus bar 30 is connected to the first window of the first outermost cell C″. Thus, the whole first cells C1 may generate the electricity.

Similarly, the whole second cells C2 may generate the electricity.

Therefore, the solar cell apparatus according to the present embodiment has improved efficiency.

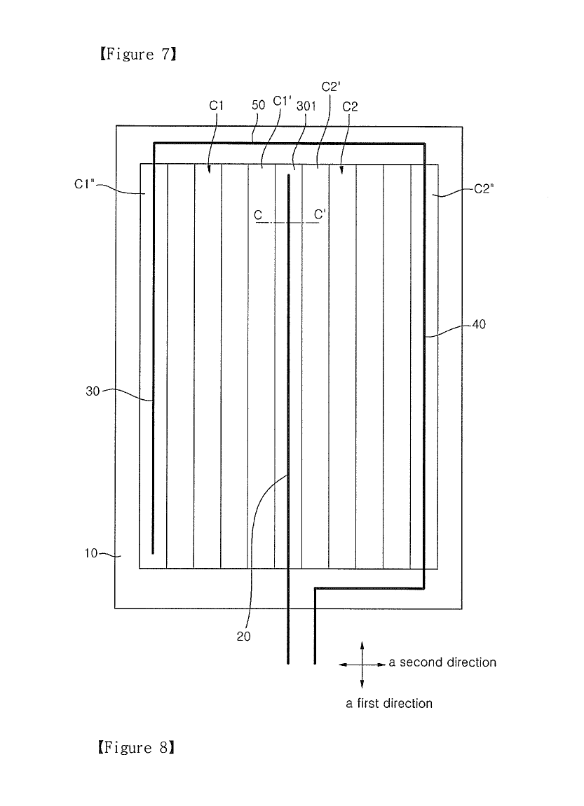

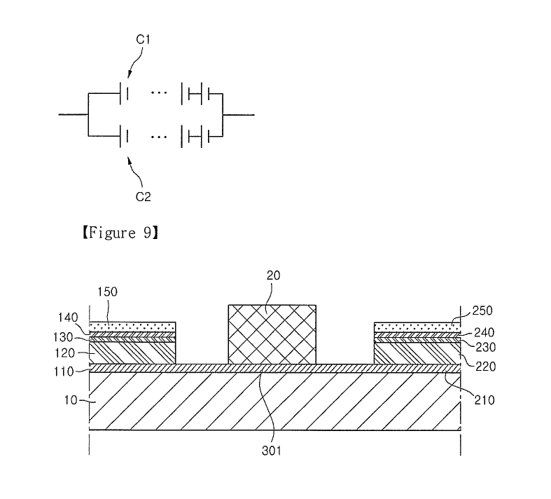

FIG. 7 is a plan view of a solar cell apparatus according to another embodiment. FIG. 8 is a circuit view of a solar cell apparatus according to another embodiment. FIG. 9 is a sectional view taken along line C-C′ of FIG. 7. The present embodiment refers to the previously described embodiment, and also, the connection electrode will be additionally described. In description of the present embodiment, this embodiment may be substantially the same as the foregoing embodiment, except changed parts of the present embodiment.

Referring to FIGS. 7 to 9, a solar cell apparatus according to the present embodiment does not include a third cell C2, but include a connection electrode 301.

The connection electrode 301 is disposed between first cells C1 and second cells C2. The connection electrode 301 is disposed between a region in which the first cells C1 are disposed and a region in which the second cells C2 are disposed. The connection electrode 301 is disposed on a support substrate 10.

The connection electrode 301 is connected to the first cells C1 and the second cells C2. In detail, the connection electrode 301 is connected to a first backside electrode 110 of a first cell C1′ adjacent thereto and a second backside electrode 210 of a second cell C2′ adjacent thereto. In further detail, the connection electrode 301 may be integrated with the first backside electrode 110 and the second backside electrode 210. That is, the connection electrode 301, the first backside electrode 110 and the second backside electrode 210 may be formed in one united body.

The connection electrode 301 may be a conductor. Examples of materials used for the connection electrode 301 may include molybdenum, etc.

A first bus bar 20 is disposed on the connection electrode 301. The first bus bar 20 directly contacts the connection electrode 301. The first bus bar 20 is connected to the first cells C1 and the second cells C2 through the connection electrode 301.

The connection electrode 301 may be integrated with the first backside electrode 110 and the second backside electrode 210. The first bus bar 20 is connected to the first cells C1 and the second cells C2 through the connection electrode 301.

Thus, disconnection between the first bus bar 20 and the first cells C1 may be prevented, and connection resistance therebetween may be reduced.

Similarly, disconnection between the first bus bar 20 and the second cells C2 may be prevented, and connection resistance therebetween may be reduced.

Therefore, the solar cell apparatus according to the present embodiment has improved efficiency.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

### INDUSTRIAL APPLICABILITY

Embodiments can be applied to solar cell apparatus fields.

1. A solar cell apparatus comprising:
a substrate;
a plurality of first cells disposed on the substrate;
a plurality of second cells disposed on the substrate; and
a first bus bar disposed between the first cells and the second cells, wherein the first bus bar being connected to the first cells and the second cells.

2. The solar cell apparatus according to claim 1, wherein the first cells are connected to each other in series, the second cells are connected to each other in series, and the first cells are connected to the second cells in parallel by the first bus bar.

3. The solar cell apparatus according to claim 1, further comprising a third cell disposed between the first cells and the second cells,
wherein the first bus bar is connected to the first cells and the second cells through the third cell.

4. The solar cell apparatus according to claim 1, further comprising:
a second bus bar connected to one of the first cells;
a third bus bar connected to one of the second cells; and
a connection part connecting the second bus bar to the third bus bar.

5. The solar cell apparatus according to claim 1, further comprising a connection electrode disposed between the substrate and the first bus bar,
wherein the first bus bar is connected to the first cells and the second cells through the connection electrode.

6. The solar cell apparatus according to claim 5, wherein the connection electrode is integrated with the lowest layer of a cell most adjacent to the first bus bar among the first cells and the lowest layer of a cell most adjacent to the first bus bar among the second cells.

7. A solar cell apparatus comprising:
a substrate;
a first cell disposed on the substrate;
a second cell disposed on the substrate, being spaced from the first cell; and
a bus bar disposed between the first cell and the second cell,
wherein the bus bar being electrically connected to the first cell and the second cell.

8. The solar cell apparatus according to claim 7, further comprising a third cell disposed between the first cell and the second cell,
wherein the bus bar is connected to the first cell and the second cell through the third cell.

9. The solar cell apparatus according to claim 8, wherein the first cell comprises:
a first backside electrode disposed on the substrate;
a first light absorption part disposed on the first backside electrode; and
a first window disposed on the first light absorption part,
wherein the second cell comprises:
a second backside electrode disposed on the substrate;
a second light absorption part disposed on the second backside electrode; and
a second window disposed on the second light absorption part,
wherein the third cell comprises:
a third backside electrode disposed on the substrate, the third backside electrode being connected to the first window and the second window;
a third light absorption part disposed on the third backside electrode; and
a third window disposed on the third light absorption part, the third window being connected to the bus bar.

10. The solar cell apparatus according to claim 9, wherein the third cell has an area greater than the sum of an area of the first cell and an area of the second cell.

11. The solar cell apparatus according to claim 8, wherein the first cell comprises:
a first backside electrode disposed on the substrate;
a first light absorption part disposed on the first backside electrode; and
a first window disposed on the first light absorption part,
wherein the second cell comprises:
a second backside electrode disposed on the substrate;
a second light absorption part disposed on the second backside electrode; and
a second window disposed on the second light absorption part,
wherein the third cell comprises:
a third backside electrode disposed on the substrate;
a third light absorption part disposed on the third backside electrode; and
a third window disposed on the third light absorption part, the third window being connected to the first backside electrode and the second backside electrode,
wherein the bus bar contacts a top surface of the third window.

12. The solar cell apparatus according to claim 7, further comprising a connection electrode disposed between the first cell and the second cell, the connection electrode being connected to the first cell and the second cell,
wherein the bus bar contacts the connection electrode.

13. The solar cell apparatus according to claim 12, wherein the first cell comprises:
a first backside electrode disposed on the substrate;
a first light absorption part disposed on the first backside electrode; and
a first window disposed on the first light absorption part,
wherein the second cell comprises:
a second backside electrode disposed on the substrate;
a second light absorption part disposed on the second backside electrode; and
a second window disposed on the second light absorption part,
wherein the connection electrode is integrated with the first backside electrode and the second backside electrode.

14. A solar cell apparatus comprising:
a first bus bar extending in a first direction;
a second bus bar extending alongside of the first bus bar;
a third bus bar extending alongside of the first bus bar, the third bus bar being electrically connected to the second bus bar;
a plurality of first cells disposed between the first bus bar and the second bus bar; and
a plurality of second cells disposed between the first bus bar and the third bus bar.

15. The solar cell apparatus according to claim 14, wherein the first cells are connected to each other in series, the second cells are connected to each other in series, and the first cells and the second cells are connected to each other in parallel.

16. The solar cell apparatus according to claim 14, further comprising a third cell directly connected to the first bus bar, the third cell being connected to the first cells and the second cells.

17. The solar cell apparatus according to claim 16, wherein the third cell has an area greater than a mean area of the first cells and a mean area of the second cells.

18. The solar cell apparatus according to claim 15, wherein the second bus bar is connected to a first outermost cell of the first cells, and
the third bus bar is connected to a second outermost cell of the second cells.
